(19) United States
(12) Patent Application Publication
(10) Pub. No.: US 2022/0066588 A1
(43) Pub. Date: Mar. 3, 2022

(54) TOUCH DISPLAY PANEL AND ELECTRONIC DEVICE

(71) Applicant: SHENZHEN ROYOLE TECHNOLOGIES CO., LTD., Shenzhen (CN)

(72) Inventors: Jiahao KANG, Shenzhen (CN); Ping LU, Shenzhen (CN); Ze YUAN, Shenzhen (CN); Haojun LUO, Shenzhen (CN)

(21) Appl. No.: 17/446,164

(22) Filed: Aug. 26, 2021

(30) Foreign Application Priority Data
Aug. 26, 2020 (CN) 202010872105.1

(51) Int. Cl. G06F 3/041; G06F 3/044

(52) U.S. Cl. CPC G06F 3/0412; G06F 3/0445; G06F 2203/04107; G06F 3/04164; G06F 2203/04111; G06F 3/0446

(57) ABSTRACT

The present disclosure relates to a touch display panel and an electronic device. The touch display panel includes: a substrate; a light-emitting unit layer located on a side of the substrate and including a cathode metal layer; multiple touch induction electrodes arranged in an array and arranged on a side of the light-emitting unit layer facing away from the substrate; multiple touch signal lines, wherein each of the touch signal lines is electrically connected to one touch induction electrode, and the touch signal lines are located between the substrate and the cathode metal layer; and an encapsulation layer located on a surface of the touch induction electrodes facing away from the substrate and covering the touch induction electrode. The touch display panel according to the present disclosure is more integrated, and has a smaller thickness and reduces steps of a preparation process.

### TECHNICAL FIELD

The present disclosure relates to the field of touch display, and in particular, to a touch display panel and an electronic device.

### BACKGROUND

With the development of a flexible display technology, a touch screen is required to be as integrated and miniaturized as possible. At present, most of self-capacitive touch display screens are in modes of add-on and on-cell and have disadvantages of large thickness, complex structure, a large number of adhesive structures and processes and high preparation costs. In addition, there are also disadvantages that are not conducive to bending of the screens and further integration and miniaturization of an electronic device.

### SUMMARY

In view of this, it is necessary to provide a touch display panel, which integrates a touch panel and a display panel, so that the touch display panel is more integrated, has a smaller thickness and reduces steps of a preparation process.

The present disclosure provides a touch display panel, including:

a substrate;

a light-emitting unit layer, where the light-emitting unit layer is located on a side of the substrate, and includes a cathode metal layer;

multiple touch induction electrodes arranged in an array, where the touch induction electrodes are arranged on a side of the light-emitting unit layer that faces away from the substrate;

multiple touch signal lines, where each of the touch signal lines is electrically connected to one touch induction electrode, and the touch signal lines are located between the substrate and the cathode metal layer; and

an encapsulation layer, where the encapsulation layer is located on a surface of the touch induction electrodes that faces away from the substrate, and covers the touch induction electrode.

Optionally, the light-emitting unit layer is provided with light-emitting parts arranged in an array; the cathode metal layer includes cathodes arranged in an array, and each of the cathodes corresponds to multiple light-emitting parts.

Optionally, an insulating layer is arranged between the touch signal lines and the touch induction electrodes, and is provided with a first through hole, and the touch signal lines are electrically connected to the touch induction electrodes by filling the first through hole with a conductive material.

Optionally, the first through hole includes a first hole position, a second hole position and a third hole position, and the first hole position, the second hole position and the third hole position are communicated with each other and separately filled with the conductive material.

Optionally, the light-emitting unit layer further includes an anode layer, the first hole position is filled with a material of the anode layer, the second hole position is filled with a material of the cathode metal layer, the third hole position is filled with a material of the touch induction electrodes, and the material of the cathode metal layer is respectively connected to the material of the anode layer and the material of the touch induction electrodes.

Optionally, the light-emitting unit layer further includes multiple anodes arranged in an array, the anodes are located between the substrate and the cathode metal layer, and the touch signal lines and the anodes are arranged at a same layer and insulated from each other.

Optionally, the touch display panel further includes a metal wire, where the touch signal lines and the metal wire are arranged at a same layer and insulated from each other.

Optionally, the touch display panel further includes a source and a drain, where the source and the drain are arranged at a same layer at an interval and insulated from each other, and the source and the drain are located between the substrate and the light-emitting unit layer; and the touch signal lines are arranged at the same layer as the source and the drain and insulated from the source and the drain, respectively.

Optionally, the touch display panel further includes a gate, where the gate is located between the substrate and the light-emitting unit layer, and the touch signal lines and the gate are arranged at a same layer and insulated from each other.

Optionally, the touch display panel further includes a light shielding layer, where the light shielding layer is located on a surface of the substrate facing the light-emitting unit layer, and the touch signal lines and the light shielding layer are arranged at a same layer and insulated from each other.

Optionally, the touch signal lines and the cathodes are arranged at a same layer.

Optionally, the light-emitting unit layer is provided with light-emitting parts arranged in an array; at least some of the touch induction electrodes correspond to the light-emitting parts, and the touch induction electrodes each are a transparent conductor.

Optionally, the touch induction electrodes each include a first touch part and a second touch part, the first touch part corresponds to the light-emitting part, the second touch part corresponds to a gap between the light-emitting parts, and the first touch part and the second touch part are connected as a whole.

Optionally, each of the touch induction electrodes corresponds to multiple light-emitting parts.

Optionally, the light-emitting unit layer is provided with light-emitting parts arranged in an array; the touch induction electrodes correspond to gaps between the light-emitting parts, and the touch induction electrodes each are a transparent conductor or a non-transparent conductor.

Optionally, each of the touch induction electrodes has multiple second through holes arranged at intervals, and each of the second through holes corresponds to the light-emitting part.

The present disclosure further provides an electronic device, including:

a device body; and

the above-mentioned touch display panel, where the touch display panel is arranged on the device body.

Therefore, in the touch display panel according to the present disclosure, the touch induction electrodes are directly prepared on the encapsulation layer to integrate a touch panel and a display panel, so that the touch display panel is more integrated, has a smaller thickness and reduces process steps.

### BRIEF DESCRIPTION OF DRAWINGS

To illustrate structural features and functions of the present disclosure more clearly, the following detailed description will be made with reference to the accompanying drawings and specific embodiments.

FIG. 1 is a schematic structural diagram illustrating a touch display panel according to an embodiment of the present disclosure;

FIG. 2 is a schematic structural diagram illustrating a touch display panel according to another embodiment of the present disclosure;

FIG. 3 is a schematic structural diagram illustrating a touch display panel according to still another embodiment of the present disclosure;

FIG. 4 is a schematic structural diagram illustrating touch induction electrodes and a light-emitting layer according to an embodiment of the present disclosure;

FIG. 5 is a schematic structural diagram illustrating touch induction electrodes and a light-emitting layer according to another embodiment of the present disclosure;

FIG. 6 is a schematic structural diagram illustrating a touch display panel according to still another embodiment of the present disclosure;

FIG. 7 is a schematic structural diagram illustrating a touch display panel according to still another embodiment of the present disclosure;

FIG. 8 is a schematic structural diagram illustrating a touch display panel according to still another embodiment of the present disclosure;

FIG. 9 is a schematic structural diagram illustrating a touch display panel according to still another embodiment of the present disclosure; and

FIG. 10 is a schematic structural diagram illustrating an electronic device according to an embodiment of the present disclosure.

### DESCRIPTION OF EMBODIMENTS

The technical solutions in the embodiments of the present disclosure will be clearly and completely described below in conjunction with the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

A touch display panel 100 is a display panel integrating a touch function and a display function. Touch screens roughly fall into four types: infrared touch screens, resistive touch screens, surface acoustic wave touch screens and capacitive touch screens. Capacitive touch screens fall into self-capacitive touch screens and mutual capacitive touch screens.

The self-capacitive touch screens each are implemented by using a transparent conductive material (such as indium tin oxide (ITO)) to make horizontal and vertical electrode arrays on a surface of glass. These horizontal and vertical electrodes form capacitors with the ground respectively. When a finger touches the capacitive screen, the capacitance of the finger will be superimposed on the capacitance of a screen body to increase the capacitance of the screen body.

The mutual capacitive touch screens each are implemented by using two metals or metal oxide materials to form a set of parallel electrode patterns (at a same layer or different layers). Because the distance between the two electrodes is very close, a capacitor is formed. When the finger touches the corresponding electrode, the capacitance between the two electrodes changes.

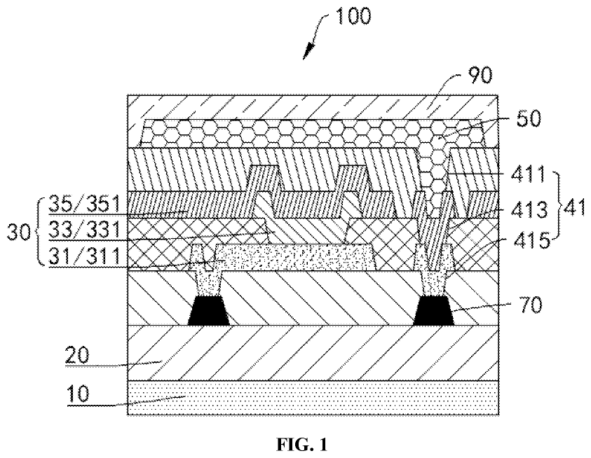

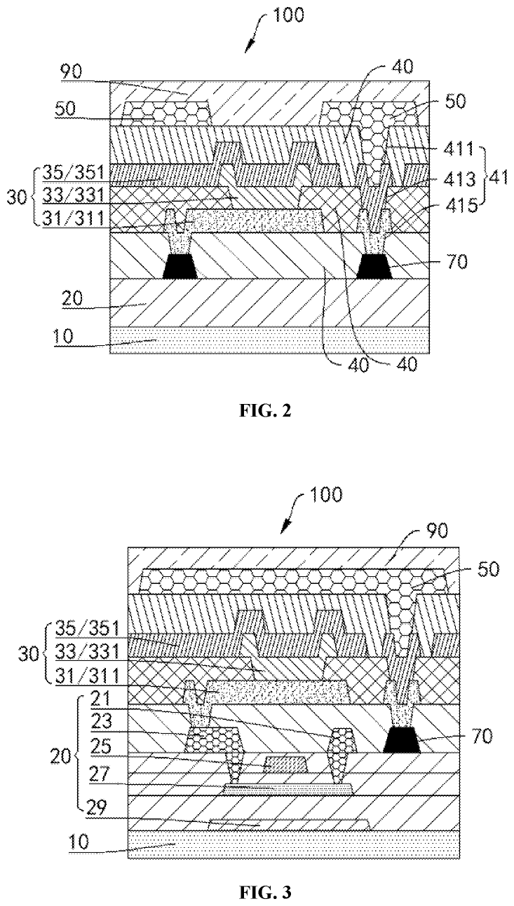

Referring to FIG. 1 and FIG. 2, a touch display panel 100 according to an embodiment of the present disclosure includes: a substrate 10; a light-emitting unit layer 30, where the light-emitting unit layer 30 is located on a side of the substrate 10, and includes a cathode metal layer 35, and the cathode metal layer 35 is configured to be connected to a low level or grounded; multiple touch induction electrodes 50 arranged in an array, where the touch induction electrodes 50 are arranged on a side of the light-emitting unit layer 30 that faces away from the substrate 10; multiple touch signal lines 70, where each of the touch signal lines 70 is electrically connected to one touch induction electrode 50, and the touch signal lines 70 are located between the substrate 10 and the cathode metal layer 35; and an encapsulation layer 90, where the encapsulation layer 90 is located on a surface of each of the touch induction electrodes 50 that faces away from the substrate 10, and covers the touch induction electrode 50.

In the touch display panel 100 according to the present disclosure, the touch induction electrodes 50 are directly prepared on the encapsulation layer 90 to integrate a touch panel and a display panel, so that the touch display panel 100 is more integrated, has a smaller thickness and reduces process steps. In addition, the integration of the touch induction electrodes and the display panel reduces the number of layers of films and reduces the thickness of the films which light needs to pass through, thereby improving the transparency and clarity of the entire touch display panel.

Optionally, the substrate 10 may be a glass substrate, or a substrate implemented by depositing a polyimide (PI) flexible substrate on a glass substrate, or the like.

Specifically, the light-emitting unit layer 30 includes an anode layer 31, a light-emitting layer 33 and a cathode metal layer 35 that are stacked in sequence. The anode layer 31 is disposed adjacent to the substrate 10, and the anode layer 31 includes multiple anodes 311 arranged in an array. The light-emitting layer 33 includes light-emitting parts 331 arranged in an array. One light-emitting part 331 corresponds to one anode 311. Each of the light-emitting parts 331 forms one sub-pixel. Three adjacent sub-pixels that can emit red, blue and green light respectively are formed in one pixel. A color and brightness of the pixel can be adjusted by controlling the proportion of the red, blue and green light of the three sub-pixels. The cathode metal layer 35 covers the entire light-emitting layer 33.

Optionally, the touch signal lines 70 and the touch induction electrodes 50 may be arranged at a same layer or at different layers. When the touch signal lines 70 and the touch induction electrodes 50 are arranged at different layers, the layer at which the touch induction electrodes 50 are located has more space for use as touch electrodes, which improves the touch sensitivity of the touch display panel 100.

When the touch signal lines 70 and the touch induction electrodes 50 are arranged at the same layer, the cathode metal layer 35 may be a metal layer on an entire surface. When the touch signal lines 70 and the touch induction electrodes 50 are arranged at different layers, the cathode metal layer 35 is patterned. Specifically, the cathode metal layer 35 includes cathodes 351 arranged in an array, and each of the cathodes 351 corresponds to multiple light-emitting parts 331. Patterning the cathode metal layer 35 can reduce the reflection of ambient light by the cathode metal layer 35 and improve image display quality of the touch display panel 100.

Optionally, referring to FIG. 3, in some embodiments, the touch display panel 100 according to the present disclosure further includes a drive circuit 20, where the drive circuit 20 is located between the substrate 10 and the light-emitting unit layer 30, and is configured to drive the light-emitting unit layer 30 to emit different colors of light.

Specifically, the drive circuit 20 includes thin-film transistors arranged in an array, and the thin-film transistors each include a source 21, a drain 23, a gate 25 and an active layer 27. The source 21 and the drain 23 are arranged at the same layer at an interval, and are separately connected to the active layer 27. The source 21 or the drain 23 is electrically connected to the anode 311, and the gate 25 is insulated from the active layer 27 at a different layer, and is configured to access a gate signal. Specifically, the thin-film transistor may have a top gate structure or a bottom gate structure. When the thin-film transistor has the top gate structure, the drive circuit 20 further includes a light shielding layer 29. The light shielding layer 29 is located between the substrate 10 and the active layer 27, and is configured to prevent light from entering the active layer 27 from one side of the substrate 10 that faces away from the drive circuit 20 and affecting a signal of the drive circuit 20.

Optionally, the source 21, the drain 23 and the gate 25 may be, but are not limited to, metals such as titanium (Ti), aluminum (Al), molybdenum (Mo), copper (Cu) and gold (Au) or metal alloys, respectively, or the like.

Optionally, the active layer 27 may be, but is not limited to, a semiconductor layer such as amorphous silicon (a-Si), polysilicon (p-Si) or a metal oxide.

Referring to FIG. 1 and FIG. 2 again, in some embodiments, an insulating layer 40 is arranged between the touch signal lines 70 and the touch induction electrodes 50, the insulating layer 40 is provided with a first through hole 41, and the touch signal lines 70 are electrically connected to the touch induction electrodes 50 by filling the first through hole 41 with a conductive material. Specifically, the conductive material may be the same as a material of the metal layer between the touch induction electrodes 50 and the touch signal lines 70, i.e., the material formed at the same time as the metal layer and used for filling the metal layer when other metal layers between the touch induction electrodes 50 and the touch signal lines 70 are prepared. In addition, other metal materials may alternatively be used for filling.

In some embodiments, the first through hole 41 includes a first hole position 411, a second hole position 413 and a third hole position 415, and the first hole position 411, the second hole position 413 and the third hole position 415 are communicated with each other and separately filled with the conductive material. Specifically, the first hole position 411, the second hole position 413 and the third hole position 415 may be filled with a same conductive material, such as a conductive material the same as a material of the touch induction electrodes 50; or may be filled with different conductive materials. For example, in some embodiments, the first hole position 411 is filled with a material of the touch to induction electrodes 50, the second hole position 413 is filled with a material of the cathode metal layer 35, the third hole position 415 is filled with a material of the anode layer 31, and the material of the cathode metal layer 35 is connected to the material of the anode layer 31 and the material of the touch induction electrodes 50, so as to electrically connect the touch induction electrodes 50 to the touch signal lines 70.

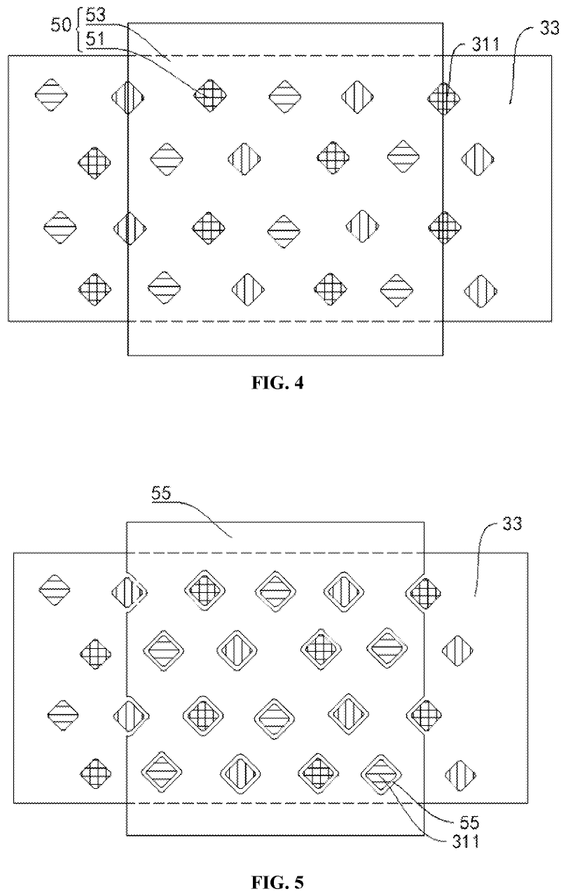

Referring to FIG. 1 and FIG. 4, in some embodiments, at least some of the touch induction electrodes 50 correspond to the light-emitting parts 331, i.e., orthographic projections of the touch induction electrodes 50 on the substrate 10 at least partially overlap with orthographic projections of the light-emitting parts 331 on the substrate 10. When the touch induction electrodes 50 correspond to the light-emitting parts 331, the touch induction electrodes 50 are each a transparent conductor, such as ITO, so that light emitted from the light-emitting unit layer 30 can freely pass through the touch induction electrodes 50.

Optionally, the touch induction electrodes 50 each include a first touch part 51 and a second touch part 53, the first touch part 51 corresponds to the light-emitting part 331, the second touch part 53 corresponds to a gap between the light-emitting parts 331, and the first touch part 51 and the second touch part 53 are connected as a whole.

Optionally, each of the touch induction electrodes 50 corresponds to multiple light-emitting parts 331.

Referring to FIG. 2 and FIG. 5, in some embodiments, the touch induction electrodes 50 each correspond to a gap between the light-emitting parts 331, i.e., the touch induction electrodes 50 are staggered from the light-emitting parts 331, or orthographic projections of the touch induction electrodes 50 on the substrate 10 and orthographic projections of the light-emitting parts 331 on the substrate 10 do not have an overlapped region (are staggered). In this case, the touch induction electrodes 50 each may be a transparent conductor or a non-transparent conductor.

Referring to FIG. 5, in some embodiments, each of the touch induction electrodes 50 has multiple second through holes 55 arranged at intervals, and each of the second through holes 55 corresponds to the light-emitting part 331. The touch induction electrodes 50 each are provided with the second through holes 55 corresponding to the light-emitting parts 331, which can prevent the emission of light from the light-emitting parts 331 from being affected when the touch induction electrode 50 is a non-transparent conductor.

In some embodiments, the touch display panel 100 according to the present disclosure further includes a metal wire (not shown), where the metal wire is located between the substrate 10 and the touch induction electrodes 50, and the touch signal lines 70 and the metal wire are arranged at a same layer and insulated from each other. That is, the touch signal lines 70 each may be a metal wire arranged at the same layer as any conductive layer between the substrate 10 and the touch induction electrodes 50, such as a metal wire arranged at the same layer as the cathode metal layer 35, the anode layer 31, the source 21, the drain 23, the gate 25, the light shielding layer 29 and the like. In addition, it is also possible to provide a new metal wire layer as touch signal lines 70 between the substrate 10 and the touch induction electrodes 50.

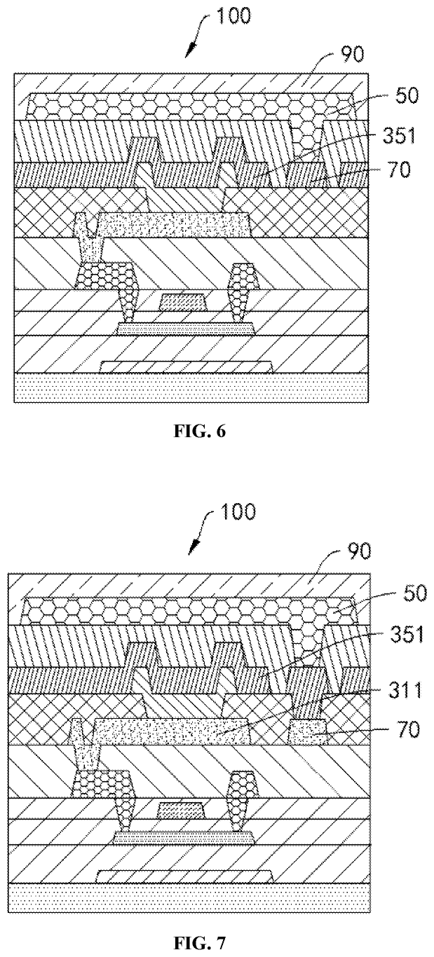

Referring to FIG. 6, in some embodiments, the touch signal lines 70 and the cathodes 351 are arranged at a same layer. That is, the touch signal lines 70 and the cathodes 351 are formed in a same process or process step. For example, the entire metal layer is formed first, and then the touch signal lines 70 and the cathodes 351 are formed through photoetching.

Referring to FIG. 7, in some embodiments, the touch signal lines 70 and the anodes 311 are arranged at a same layer and insulated from each other. That is, the touch signal lines 70 and the anodes 311 are formed in a same process or process step. For example, the entire metal layer is formed first, and then the touch signal lines 70 and the anodes 311 are formed through photoetching.

Referring to FIG. 3 again, in some embodiments, the touch signal lines 70 are arranged at the same layer as the source 21 and the drain 23 and insulated from the source 21 and the drain 23. That is, the touch signal lines 70 and the source 21 and the drain 23 are formed in a same process or process step. For example, the entire metal layer is formed first, and then the touch signal lines 70, the source 21 and the drain 23 are formed through photoetching.

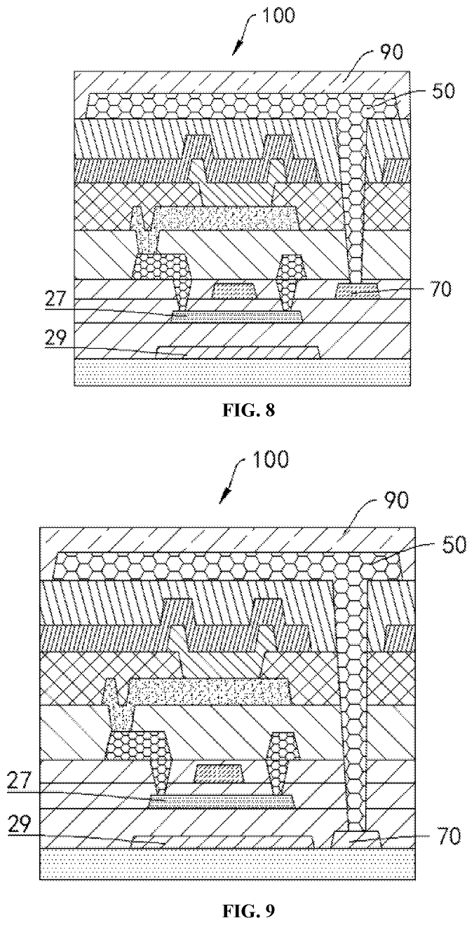

Referring to FIG. 8, in some embodiments, the touch signal lines 70 and the gate 25 are arranged at a same layer and insulated from each other. That is, the touch signal lines and the gate 25 are formed in a same process or process step. For example, the entire metal layer is formed first, and then the touch signal lines and the gate 25 are formed through photoetching.

Referring to FIG. 9, in some embodiments, the touch signal lines 70 and the light shielding layer 29 are arranged at a same layer and insulated from each other. That is, the touch signal lines 70 and the light shielding layer 29 are formed in a same process or process step. For example, the entire metal layer is formed first, and then the touch signal lines 70 and the light shielding layer 29 are formed through photoetching.

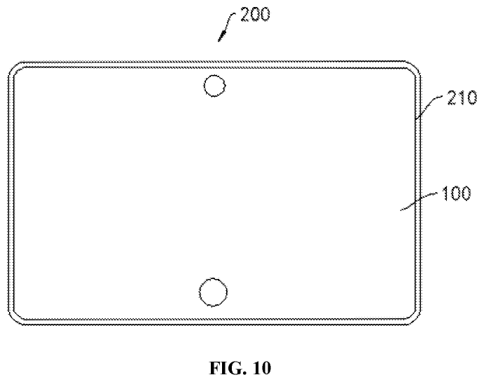

Referring to FIG. 10, an embodiment of the present disclosure further provides an electronic device 200, including:

a device body 210; and

the touch display panel 100 according to the embodiment of the present disclosure, where the touch display panel 100 is arranged on the device body 210.

The electronic device 200 according to the present disclosure includes, but is not limited to, devices with display functions such as a display, a computer, a television, a tablet computer, a mobile phone, an e-reader, a smart watch with a display screen, a smart band and a player with a display screen.

The above are merely specific implementations of the present disclosure, but the protection scope of the present disclosure is not limited thereto. Any person skilled in the art may easily think of various equivalent modifications or replacements within the technical scope disclosed in the present disclosure, and these modifications or replacements should fall within the protection scope of the present disclosure. Therefore, the protection scope of the present disclosure should be subject to the protection scope of the claims.

What is claimed is:

1. A touch display panel, comprising:
a substrate;
a light-emitting unit layer, wherein the light-emitting unit layer is located on a side of the substrate, and comprises a cathode metal layer;
multiple touch induction electrodes arranged in an array, wherein the touch induction electrodes are arranged on a side of the light-emitting unit layer that faces away from the substrate;
multiple touch signal lines, wherein each of the touch signal lines is electrically connected to one touch induction electrode, and the touch signal lines are located between the substrate and the cathode metal layer; and
an encapsulation layer, wherein the encapsulation layer is located on a surface of the touch induction electrodes that faces away from the substrate, and covers the touch induction electrode.

2. The touch display panel according to claim 1, wherein the light-emitting unit layer is provided with light-emitting parts arranged in an array; the cathode metal layer comprises cathodes arranged in an array, and each of the cathodes corresponds to multiple light-emitting parts.

3. The touch display panel according to claim 2, wherein an insulating layer is arranged between the touch signal lines and the touch induction electrodes, and is provided with a first through hole, and the touch signal lines are electrically connected to the touch induction electrodes by filling the first through hole with a conductive material.

4. The touch display panel according to claim 3, wherein the first through hole comprises a first hole position, a second hole position and a third hole position, and the first hole position, the second hole position and the third hole position are communicated with each other and separately filled with the conductive material.

5. The touch display panel according to claim 4, wherein the light-emitting unit layer further comprises an anode layer, the first hole position is filled with a material of the anode layer, the second hole position is filled with a material of the cathode metal layer, the third hole position is filled with a material of the touch induction electrodes, and the material of the cathode metal layer is respectively connected to the material of the anode layer and the material of the touch induction electrodes.

6. The touch display panel according to claim 2, wherein the light-emitting unit layer further comprises multiple anodes arranged in an array, the anodes are located between the substrate and the cathode metal layer, and the touch signal lines and the anodes are arranged at a same layer and insulated from each other.

7. The touch display panel according to claim 2, further comprising a metal wire, wherein the touch signal lines and the metal wire are arranged at a same layer and insulated from each other.

8. The touch display panel according to claim 2, further comprising a source and a drain, wherein the source and the drain are arranged at a same layer at an interval and insulated from each other, and the source and the drain are located between the substrate and the light-emitting unit layer; and the touch signal lines are arranged at the same layer as the source and the drain and insulated from the source and the drain, respectively.

9. The touch display panel according to claim 2, further comprising a gate, wherein the gate is located between the substrate and the light-emitting unit layer and the touch signal lines and the gate are arranged at a same layer and insulated from each other.

10. The touch display panel according to claim 2, further comprising a light shielding layer, wherein the light shielding layer is located on a surface of the substrate facing the light-emitting unit layer, and the touch signal lines and the light shielding layer are arranged at a same layer and insulated from each other.

11. The touch display panel according to claim 2, wherein the touch signal lines and the cathodes are arranged at a same layer.

12. The touch display panel according to claim 1, wherein the light-emitting unit layer is provided with light-emitting parts arranged in an array; at least some of the touch induction electrodes correspond to the light-emitting parts, and the touch induction electrodes each are a transparent conductor.

13. The touch display panel according to claim 12, wherein the touch induction electrodes each comprise a first touch part and a second touch part, the first touch part corresponds to the light-emitting part, the second touch part corresponds to a gap between the light-emitting parts, and the first touch part and the second touch part are connected as a whole.

14. The touch display panel according to claim 13, wherein each of the touch induction electrodes corresponds to multiple light-emitting parts.

15. The touch display panel according to claim 1, wherein the light-emitting unit layer is provided with light-emitting parts arranged in an array; the touch induction electrodes correspond to gaps between the light-emitting parts, and the touch induction electrodes each are a transparent conductor or a non-transparent conductor.

16. The touch display panel according to claim 15, wherein each of the touch induction electrodes has multiple second through holes arranged at intervals, and each of the second through holes corresponds to the light-emitting part.

17. An electronic device, comprising:
a device body; and
a touch display panel arranged on the device body, wherein the touch display panel comprises:
a substrate;
a light-emitting unit layer, wherein the light-emitting unit layer is located on a side of the substrate, and comprises a cathode metal layer;
multiple touch induction electrodes arranged in an array, wherein the touch induction electrodes are arranged on a side of the light-emitting unit layer that faces away from the substrate;
multiple touch signal lines, wherein each of the touch signal lines is electrically connected to one touch induction electrode, and the touch signal lines are located between the substrate and the cathode metal layer; and
an encapsulation layer, wherein the encapsulation layer is located on a surface of the touch induction electrodes that faces away from the substrate, and covers the touch induction electrode.
